(19) United States
(12) Patent Application Publication
(10) Pub. No.: US 2007/0202703 A1
(43) Pub. Date: Aug. 30, 2007

(54) Polishing composition and polishing method

(76) Inventors: Mikikazu Shimizu, Komaki-shi (JP); Takehiko Nakajima, Ichinomiya-shi (JP)

Correspondence Address: VIDAS, ARRETT & STEINKRAUS, P.A., SUITE 400, 6640 SHADY OAK ROAD, EDEN PRAIRIE, MN, 55344, US

(21) Appl. No.: 11/711,234

(22) Filed: Feb. 27, 2007

(30) Foreign Application Priority Data
Feb. 28, 2006 (JP) 2006-053243

(51) Int. Cl. H01L 21/461; B24D 3/02; C09K 3/14

(52) U.S. Cl. 438/692; 51/308; 51/307; 438/693

(57) ABSTRACT

A polishing composition contains silica abrasive grains and an iodine compound. The silica abrasive grains exhibit a negative zeta potential in the polishing composition. The silica abrasive grains have an average primary particle size of 30 nm or smaller, and the polishing composition has a pH of 4 or lower. The polishing composition is suitable for polishing a polysilicon film and a silicon nitride film.

### BACKGROUND OF THE INVENTION

The present invention relates to a polishing composition used, for example, in polishing of a polysilicon film and a silicon nitride film in semiconductor device production, and to a polishing method using this polishing composition.

In recent years, the field of semiconductor device production has been faced with the necessity of simultaneously polishing a polysilicon film and a silicon nitride film. However, no previously known polishing compositions can polish both a polysilicon film and a silicon nitride film at a sufficiently high removal rate compared with that for a silicon dioxide film.

Polishing compositions having an acidic pH have heretofore been employed for polishing a silicon nitride film. For example, Japanese Laid-Open Patent Publication No. 2004-214667 has disclosed a polishing composition having a pH set to 1 to 5 by adding phosphoric acid, nitric acid, or fluoric acid. On the other hand, polishing compositions having an alkaline pH have been employed for polishing a polysilicon film (see e.g., Japanese Laid-Open Patent Publication No. 7-249600).

### SUMMARY OF THE INVENTION

Accordingly, an object of the present invention is to provide a polishing composition suitable for polishing a polysilicon film and a silicon nitride film, and a polishing method using this polishing composition.

To attain the object, the present invention provides a polishing composition which contains silica abrasive grains and an iodine compound. The silica abrasive grains exhibit a negative zeta potential in the polishing composition and have an average primary particle size of 30 nm or smaller. The polishing composition has a pH of 4 or lower.

The present invention also provides a polishing method which includes simultaneously polishing a polysilicon film and a silicon nitride film by use of the polishing composition.

Other aspects and advantages of the invention will become apparent from the following description illustrating by way of example the principles of the invention.

### DETAILED DESCRIPTION OF THE PREFERRED EMBODIMENTS

Hereinafter, one embodiment of the present invention will be described

A polishing composition of this embodiment, which is obtained by mixing silica abrasive grains, an iodine compound, and water, comprises silica abrasive grains, an iodine compound, and water and has a pH of 4 or lower. This polishing composition is used, for example, in polishing of a polysilicon film and a silicon nitride film.

The silica abrasive grains in the polishing composition are responsible for mechanically polishing an object to be polished.

The silica abrasive grains contained in the polishing composition may be any of colloidal silica, fumed silica, and powdered calcined silica. Among them, the colloidal silica is preferable. The colloidal silica, when used as the silica abrasive grains contained in the polishing composition, reduces surface defects in an object to be polished caused by polishing the object to be polished by use of the polishing composition.

When the silica abrasive grains contained in the polishing composition have an average primary particle size less than 3 nm, more specifically, less than 4 nm, and even more specifically, less than 5 nm, a removal rate by the polishing composition might be insufficient for practical use. Thus, the silica abrasive grains contained in the polishing composition have an average primary particle size of preferably 3 nm or larger, more preferably 4 nm or larger, most preferably 5 nm or larger, for obtaining a practical removal rate.

On the other hand, the silica abrasive grains contained in the polishing composition must have an average primary particle size of 30 nm or smaller for obtaining the polishing composition suitable for polishing a polysilicon film and a silicon nitride film. This is because the removal rate of a polysilicon film is lowered when the silica abrasive grains have an average primary particle size exceeding 30 nm. However, when the silica abrasive grains contained in the polishing composition have an average primary particle size exceeding 25 nm, and more specifically, exceeding 20 nm, albeit an average primary particle size of 30 nm or smaller, the removal rate of a polysilicon film tends to be slightly lowered. Thus, the silica abrasive grains contained in the polishing composition have an average primary particle size of preferably 25 nm or smaller, more preferably 20 nm or smaller. The average primary particle size of the silica abrasive grains is calculated on the basis of the specific surface of the silica abrasive grains measured by a BET method and the particle density of the silica abrasive grains.

When the polishing composition has a content of the silica abrasive grains less than 0.1% by mass, more specifically, less than 0.3% by mass, and even more specifically, less than 0.5% by mass, a removal rate by the polishing composition might be insufficient for practical use. Thus, the polishing composition has a content of the silica abrasive grains of preferably 0.1% by mass or more, more preferably 0.3% by mass or more, most preferably 0.5% by mass or more, for obtaining a practical removal rate.

On the other hand, when the polishing composition has a content of the silica abrasive grains exceeding 15% by mass, more specifically, exceeding 10% by mass, and even more specifically, exceeding 8% by mass, the removal rate of a silicon dioxide film might significantly rise as compared with those of a polysilicon film and a silicon nitride film. A polishing composition that provides a high removal rate of a silicon dioxide film is unsuitable for polishing a polysilicon film and a silicon nitride film in semiconductor device production. Thus, the polishing composition has a content of the silica abrasive grains of preferably 15% by mass or lower, more preferably 10% by mass or lower, most preferably 8% by mass or lower.

The silica abrasive grains must exhibit a negative zeta potential in the polishing composition for obtaining the polishing composition suitable for polishing a polysilicon film and a silicon nitride film in semiconductor device production. This is because the removal rate of a silicon nitride film is lowered or the removal rate of a silicon dioxide film is rendered higher than those of a polysilicon film and a silicon nitride film when the silica abrasive grains exhibit a zero or positive zeta potential. However, when the silica abrasive grains exhibit a zeta potential higher than −10 mV, and more specifically, higher than −15 mV, albeit a negative zeta potential, in the polishing composition, the removal rate of a silicon nitride film tends to be slightly lowered or the removal rate of a silicon dioxide film tends to be slightly raised. Thus, the silica abrasive grains exhibit a zeta potential of preferably −10 mV or lower, and more preferably −15 mV or lower, in the polishing composition.

In this embodiment, the silica abrasive grains carry aluminum particles on the surface in order to allow the silica abrasive grains to have a negative zeta potential in the polishing composition of this embodiment having a pH of 4 or lower. Naturally, the aluminum particles have a particle size smaller than that of the silica abrasive grains.

The iodine compound in the polishing composition has the function of improving the removal rate of a polysilicon film by the polishing composition.

The iodine compound contained in the polishing composition may be any of orthoperiodic acid (H₅IO₆), metaperiodic acid (HIO₄), mesoperiodic acid (H₃IO₅), 2-orthoperiodic acid (H₈I₂O₁₁), and 2-mesoperiodic acid (H₄I₂O₉). Among them, the orthoperiodic acid is preferable. The orthoperiodic acid is relatively easily obtainable. Besides, a stable polishing composition is easily obtained when the orthoperiodic acid is used as the iodine compound contained in the polishing composition.

The content of the iodine compound in the polishing composition must be an amount allowing the polishing composition to have a pH of 4 or lower for obtaining the polishing composition suitable for polishing a polysilicon film and a silicon nitride film. The removal rate of a polysilicon film is lowered when the content of the iodine compound in the polishing composition is smaller than an amount allowing the polishing composition to have a pH of 4, that is, when the polishing composition has a pH exceeding 4. However, when the polishing composition has a pH exceeding 3, and more specifically, exceeding 2.5, albeit a pH of 4 or lower, the removal rate of a polysilicon film might be lowered slightly. Thus, the polishing composition has a pH of preferably 3 or lower, more preferably 2.5 or lower. In other words, the content of the iodine compound in the polishing composition is preferably an amount allowing the polishing composition to have a pH of 3 or lower, more preferably an amount allowing the polishing composition to have a pH of 2.5 or lower.

On the other hand, when the polishing composition has a pH less than 1, and more specifically, less than 1.5, the zeta potential of the silica abrasive grains in the polishing composition is raised, with the result that the removal rate of a silicon nitride film might be lowered or the removal rate of a silicon dioxide film might be raised. Thus, the polishing composition has a pH of preferably 1 or higher, more preferably 1.5 or higher. In other words, the content of the iodine compound in the polishing composition is preferably an amount allowing the polishing composition to have a pH of 1 or higher, more preferably an amount allowing the polishing composition to have a pH of 1.5 or higher.

According to this embodiment, advantages described below are obtained.

The silica abrasive grains exhibit a negative zeta potential in the polishing composition. As a result, the polishing composition of this embodiment has the ability to polish a silicon nitride film at a sufficiently high removal rate compared with that for a silicon dioxide film. The content of the iodine compound in the polishing composition is an amount allowing the polishing composition to have a pH of 4 or lower. As a result, the polishing composition of this embodiment has the ability to polish a polysilicon film at a sufficiently high removal rate compared with that for a silicon dioxide film. Thus, the polishing composition of this embodiment is suitable for polishing a polysilicon film and a silicon nitride film.

In this embodiment, the polishing composition has a pH set to 4 or lower by adding the iodine compound. The pH of the polishing composition can be set to 4 or lower even if a chlorine compound (e.g., perchloric acid) structurally similar to the iodine compound is employed instead of the iodine compound. In this case, however, the removal rate of a polysilicon film is lowered, and the polishing composition suitable for polishing a polysilicon film and a silicon nitride film cannot be obtained. Likewise, when an acid such as phosphoric acid, nitric acid, or acetic acid is employed instead of the iodine compound, the removal rate of a polysilicon film is lowered, and the polishing composition suitable for polishing a polysilicon film and a silicon nitride film cannot be obtained. By contrast, when the pH of the polishing composition is set to 4 or lower by use of the iodine compound, the removal rate of a polysilicon film is raised, and the polishing composition suitable for polishing a polysilicon film and a silicon nitride film can be obtained.

The embodiment described above may be modified as follows.

A chelating agent, water-soluble polymer, surfactant, antiseptic, fungicide, anticorrosive, and the like may be added, as required, to the polishing composition of the embodiment.

The polishing composition of the embodiment may be used in polishing of objects to be polished other than a polysilicon film and a silicon nitride film.

The polishing composition of the embodiment may be prepared by diluting a stock solution of the polishing composition with water. The stock solution has a volume smaller than that of the polishing composition and as such, is advantageous for storage and transport.

Next, Examples and Comparative Examples of the present invention will be described.

The polishing compositions of Examples 1 to 6 and Comparative Examples 1 to 17 were prepared by mixing abrasive grains with water as required and further mixing the mixture with an iodine compound or a compound as a substitute therefor as required so as to give a desired pH value. The details of the abrasive grains and the iodine compound or the compound as a substitute therefor in the polishing compositions, the pH of the polishing compositions, and the zeta potential of the abrasive grains in the polishing compositions are shown in Table 1. The zeta potential was measured with an ultrasonic-system particle size distribution/zeta potential measurement instrument DT-1200 of Dispersion Technology, Inc.

In Table 1, “SiO₂₍₁₂₎” denotes colloidal silica having an average primary particle size of 12 nm, “SiO₂₍₈₎” denotes colloidal silica having an average primary particle size of 8 nm, “SiO₂₍₁₂₎*” denotes colloidal silica carrying aluminum particles on the surface and having an average primary particle size of 12 nm, “SiO₂₍₃₄₎*” denotes colloidal silica carrying aluminum particles on the surface and having an average primary particle size of 34 nm, “Al₂O₃₍₂₅₎” denotes alumina sol having an average primary particle size of 25 nm, “Al₂O₃₍₉₀₎” denotes alumina sol having an average primary particle size of 90 nm, “H₅IO₆” denotes orthoperiodic acid, “NH₃” denotes ammonia, “H₃PO₄” denotes phosphoric acid, “H₅ClO₆” denotes orthoperchloric acid, “CH₃COOH” denotes acetic acid, “HNO₃” denotes nitric acid, and H₂SO₄ denotes sulfuric acid.

The polishing compositions of Examples 1 to 6 and Comparative Examples 1 to 17 were separately used to polish a substrate with a polysilicon film, a substrate with a silicon nitride film, and a substrate with a silicon dioxide film (TEOS film) under the conditions shown in Table 2. The size of each substrate was 32 mm long×32 mm wide.

The “removal rate” columns of Table 1 show the removal rates of the polysilicon film, the silicon nitride film, and the silicon dioxide film determined by dividing a difference in the thickness of each substrate between before and after polishing by a polishing time. The thicknesses of the substrates were measured with an interferometric film thickness measurement instrument LAMBDA ACE VM-2030 of DAINIPPON SCREEN MFG. CO., LTD.

The “selected ratio” columns of Table 1 show the ratios of the removal rate of the polysilicon film to that of the silicon dioxide film and the ratios of the removal rate of the silicon nitride film to that of the silicon dioxide film.

TABLE 1

| | | | Iodine | | | | | | | |
|---|---|---|---|---|---|---|---|---|---|---|
| | | | compound | | | | | | | |
| | | | or | | | Removal rate | | | | |
| | | | compound as | | | [nm/hr.] | | | Selected ratio | |
| | Abrasive grains | | substitute | | Zeta | | | Silicon | Polysilicon | Silicon nitride |
| | | Content [% | therefor | | potential | Polysilicon | Silicon | dioxide | film/silicon | film/silicon |
| | Name | by mass] | Name | pH | [mV] | film | nitride film | film | dioxide film | dioxide film |
| Ex. 1 | SiO₂₍₁₂₎* | 1 | H₅IO₆ | 2.0 | −20 | 49 | 44 | 1.1 | 45 | 40 |
| Ex. 2 | SiO₂₍₁₂₎* | 2 | H₅IO₆ | 2.0 | −20 | 65 | 57 | 3.6 | 18 | 16 |
| Ex. 3 | SiO₂₍₁₂₎* | 5 | H₅IO₆ | 2.0 | −20 | 54 | 56 | 6.1 | 8.9 | 9.2 |
| Ex. 4 | SiO₂₍₁₂₎* | 10 | H₅IO₆ | 2.0 | −20 | 55 | 62 | 9.9 | 5.6 | 6.3 |
| Ex. 5 | SiO₂₍₁₂₎* | 2 | H₅IO₆ | 1.5 | −18 | 83 | 27 | 4.2 | 20 | 6.4 |
| Ex. 6 | SiO₂₍₁₂₎* | 5 | H₅IO₆ | 1.5 | −18 | 81 | 34 | 5.6 | 14 | 6.1 |
| C. Ex. 1 | — | — | H₅IO₆ | 2.0 | — | 23 | 1.1 | 0.0 | — | — |
| C. Ex. 2 | SiO₂₍₁₂₎ | 2 | H₅IO₆ | 2.0 | 5 | 60 | 20 | 18 | 3.3 | 1.1 |
| C. Ex. 3 | SiO₂₍₈₎ | 5 | H₅IO₆ | 7.2 | −18 | 7.9 | 3.4 | 1.7 | 4.6 | 2.0 |
| C. Ex. 4 | SiO₂₍₈₎ | 5 | H₅IO₆ | 2.2 | 8 | 79 | 26 | 18 | 4.4 | 1.4 |
| C. Ex. 5 | SiO₂₍₁₂₎* | 5 | — | 3.5 | −39 | 1.4 | 47 | 0.6 | 2.3 | 78 |
| C. Ex. 6 | SiO₂₍₁₂₎* | 5 | NH₃ | 4.5 | −58 | 5.8 | 37 | 0.9 | 6.4 | 41 |
| C. Ex. 7 | SiO₂₍₃₄₎* | 5 | — | 3.1 | −28 | 3.2 | 40 | 2.4 | 1.3 | 17 |
| C. Ex. 8 | SiO₂₍₃₄₎* | 5 | H₅IO₆ | 2.1 | −20 | 15 | 54 | 12 | 1.3 | 4.5 |
| C. Ex. 9 | SiO₂₍₁₂₎* | 2 | H₃PO₆ | 2.0 | −20 | 2.2 | 42 | 2.7 | 0.8 | 16 |
| C. Ex. 10 | SiO₂₍₁₂₎* | 2 | H₅CIO₆ | 2.0 | −20 | 1.7 | 41 | 3.2 | 0.5 | 13 |
| C. Ex. 11 | SiO₂₍₁₂₎* | 2 | CH₃COOH | 2.0 | −20 | 2.6 | 53 | 2.7 | 1.0 | 20 |
| C. Ex. 12 | SiO₂₍₁₂₎* | 2 | HNO₃ | 2.0 | −20 | 2.9 | 45 | 3.4 | 0.9 | 13 |
| C. Ex. 13 | SiO₂₍₁₂₎* | 2 | H₂SO₄ | 2.0 | −20 | 1.5 | 44 | 4.8 | 0.3 | 9.2 |
| C. Ex. 14 | Al₂O₃(25) | 5 | — | 3.8 | 33 | 42 | 1.3 | 1.7 | 25 | 0.8 |
| C. Ex. 15 | Al₂O₃(25) | 5 | H₅IO₆ | 2.8 | 34 | 45 | 0.9 | 2.5 | 18 | 0.4 |
| C. Ex. 16 | Al₂O₃(90) | 5 | — | 4.9 | 32 | 20 | 0.0 | 1.7 | 12 | 0.0 |
| C. Ex. 17 | Al₂O₃(90) | 5 | H₅IO₆ | 3.2 | 33 | 32 | 0.7 | 1.5 | 21 | 0.5 |

TABLE 2

Polishing machine: EJ-380IN (manufactured by Engis Japan Corp.)
Surface plate diameter: 380 mm
Polishing pad: IC-1000/Suba400 (manufactured by Nitta Haas Inc.)
Polishing pressure: 2.64 psi (=18.20 kPa)
The number of revolutions of surface plate: 60 rpm
Linear velocity: 42 m/min. (at polishing head)
Rate of feed of polishing composition: 100 mL/min.
Dressing: In-Situ (#100 diamond used)
Polishing time: 60 sec.

As shown in Table 1, a practically satisfactory level of a removal rate was obtained for both the polysilicon film and the silicon nitride film in Examples 1 to 6. Moreover, both the removal rates of the polysilicon film and the silicon nitride film were higher by a practically satisfactory degree than the removal rate of the silicon dioxide film in Examples 1 to 6. By contrast, in Comparative Examples 1 to 17, a practically satisfactory level of a removal rate was not obtained for at least either of the polysilicon film or the silicon nitride film or the removal rates of the polysilicon film and the silicon nitride film were not higher by a practically satisfactory degree than the removal rate of the silicon dioxide film.

1. A polishing composition comprising silica abrasive grains and an iodine compound,
wherein the silica abrasive grains exhibit a negative zeta potential in the polishing composition and have an average primary particle size of 30 nm or smaller, and the polishing composition has a pH of 4 or lower.

2. The polishing composition according to claim 1, wherein the silica abrasive grains carry aluminum particles on the surface.

3. The polishing composition according to claim 1, wherein the silica abrasive grains exhibit a zeta potential of −10 mV in the polishing composition.

4. The polishing composition according to claim 1, wherein the polishing composition has a pH of 2.5 or lower.

5. The polishing composition according to claim 1, wherein the iodine compound is orthoperiodic acid.

6. The polishing composition according to claim 1, wherein the polishing composition has a content of the silica abrasive grains of 8% by mass or lower.

7. The polishing composition according to claim 1, wherein the silica abrasive grains have an average primary particle size of 3 to 30 nm.

8. The polishing composition according to claim 1, wherein the polishing composition is used in polishing of a polysilicon film and a silicon nitride film.

9. A polishing composition comprising:
colloidal silica the content of which in the polishing composition is 8% by mass or lower, the colloidal silica exhibiting a negative zeta potential in the polishing composition and has an average primary particle size of 3 to 30 nm;
orthoperiodic acid the content of which in the polishing composition is an amount allowing the polishing composition to have a pH of 1 to 4; and
water.

10. A polishing method comprising simultaneously polishing a polysilicon film and a silicon nitride film by use of a polishing composition that contains silica abrasive grains and an iodine compound, wherein the silica abrasive grains exhibit a negative zeta potential in the polishing composition and have an average primary particle size of 30 nm or smaller, and the polishing composition has a pH of 4 or lower.
